(19) United States
(12) Patent Application Publication
(10) Pub. No.: US 2014/0374907 A1
(43) Pub. Date: Dec. 25, 2014

(54) ULTRA-THIN COPPER SEED LAYER FOR ELECTROPLATING INTO SMALL FEATURES

(71) Applicant: APPLIED MATERIALS, INC., SANTA CLARA, CA (US)

(72) Inventors: Jick M. YU, San Jose, CA (US); Rong TAO, San Jose, CA (US)

(21) Appl. No.: 14/305,906

(22) Filed: Jun. 16, 2014

Related U.S. Application Data
(60) Provisional application No. 61/839,067, filed on Jun. 25, 2013.

(51) Int. Cl. H01L 21/768; H01L 23/532

(52) U.S. Cl. CPC H01L 21/76879; H01L 23/53238; H01L 21/76847
USPC 257/751; 438/653

(57) ABSTRACT

An apparatus and process are described that allow electroplating to fill sub-micron, high aspect ratio semiconductor substrate features using a non-copper/pre-electroplating layer on at least upper portions of side walls of the features, thereby providing reliable bottom up accumulation of the electroplating fill material in the feature. This apparatus and process eliminates feature filling material voids and enhances reliability of the electroplating in the diminishing size of features associated with future technology nodes of 22, 15, 11, and 8 nm. Modification of an upper portion of a metal seed layer allows for filling of the feature using electroplated fill material accumulating from the bottom of the feature up to reliability and predictability and substantially void-free.

### CROSS-REFERENCE TO RELATED APPLICATIONS

This application claims benefit of U.S. provisional patent application Ser. No. 61/839,067, filed Jun. 25, 2013. The aforementioned related patent application is herein incorporated by reference in its entirety.

This application is related to co-pending U.S. patent application Ser. No. 13/923,979, filed Jun. 21, 2013, which claims benefit of U.S. provisional patent application Ser. No. 61/662,857, filed Jun. 21, 2012.

### BACKGROUND

1. Field

Implementations of the present disclosure generally relate to semiconductor substrates and processing and in particular to electroplating and fabrication of layers prior to electroplating.

2. Discussion of the Related Art

Integrated circuits fabricated on semiconductor substrates for very large and ultra large scale integration require multiple levels of metal layers to electrically interconnect the layers of semiconductor devices. The different levels of metal layers are separated by various insulating or dielectric layers (also known as interlevel dielectric (ILD) layers), which have features filled with conducting material (usually metal) to connect across dielectric layers.

As circuit elements are further miniaturized the dimensions of all components need to become smaller including electrical connections between various circuit elements and through and across dielectric layers. One way to reduce the size of interconnection features (trenches, lines, depressions, holes, ditches and vias or combinations thereof) is to use copper (Cu) as the interconnect material instead of conventionally used materials such as aluminum (Al). Because copper has a lower resistivity and significantly higher electromigration resistance as compared to aluminum, use of copper enables the use of higher current densities and facilitates increased device speed at higher frequencies. Thus, major integrated circuit manufacturers are transitioning from aluminum-based metallization technology to copper based technology.

Therefore a need exists for methods to fill ultra-small features such that the deposited material is free of voids, seams and other defects.

### SUMMARY

In one implementation, a substrate structure is provided. The substrate structure comprises depression forming a feature in and below a surface of a dielectric layer on a substrate, a barrier layer covering one or more side walls and a bottom surface of the feature and a metal seed layer covering the barrier layer covering one or more side walls and a bottom surface of the feature, wherein an upper portion of the metal seed layer is modified to promote bottom-up plating of a metal layer in the feature.

In another implementation, a process of making a reliable electrical connection through a dielectric layer on a substrate is provided. The process comprises depositing a barrier layer over at least one or more side walls and a bottom surface of a feature in and below a surface of a dielectric layer on the substrate, depositing a metal seed layer over the barrier layer covering the at least one or more side walls and the bottom surface of the feature and modifying an upper portion of the metal seed layer to promote bottom-up plating of a metal layer in the feature.

Implementations described herein include a device comprising a substrate having a dielectric material layer on a substrate, the layer having a void (or depression) therethrough to a surface of the substrate facing the void, wherein at least one side wall of the dielectric material layer facing the void meets the surface of said substrate facing the void and comprises at least one side wall and a bottom surface of a feature, a barrier layer coating the at least one side wall of the feature and extending to and across the bottom surface of the feature, a continuous metal seed layer coating the at least one side wall extending to and across the bottom surface of the feature, at least a remnant of a pre-electroplating layer coating at least an upper portion of the at least one side wall of the feature, but not coating the bottom surface of the feature, and a substantially void free homogeneous metal feature fill material extending from the continuous metal seed layer coating across the bottom surface of the feature and over the pre-electroplating layer coating on the at least an upper portion of the at least one side wall of the feature to substantially fill the void in the layer of dielectric material, and where present the pre-electroplating layer is disposed between the feature fill copper material and the metal seed layer coating the at least one side wall of the feature. And the copper seed layer coating the at least one side wall of the feature can be indistinguishable from the feature fill copper material.

A nominal minimal dimension across a gap in the surface of the dielectric material layer created by the aperture therein is 32 nm, 15 nm, 11 nm or less.

The continuous metal seed layer coating the at least one side wall extending to and across the bottom surface of the feature is one metal selected from a group of metals which include Cu or Pd, or is copper or an alloy thereof.

The pre-electroplating barrier layer is a metal selected from the group consisting of Cu bondable material having an electrical resistance greater than (or a conductivity less than) Cu, wherein the feature is filled with copper, and wherein the pre-electroplating layer is disposed between the copper fill material and the barrier layer covering at least an upper portion of the one or more side walls of the dielectric material. The group consisting of copper bondable material having an electrical resistance greater than copper pre-electroplating layer is comprised of a metal selected from a group consisting of one or a combination of elements and alloys of Co, Rh, Pd, Ni, Zn, Cd, Cr, W, Mo, and Ru, and in particular cobalt.

The pre-electroplating barrier layer is 1 Å to 20 Å thick as measured by X-ray fluorescence measurement techniques as measured at multiple points in a statistical valid survey of the thickness.

Further implementations include a device. The device comprises a dielectric material layer on a substrate, wherein the dielectric material layer has a feature extending therethrough to a surface of the substrate facing the feature, wherein at least one side wall of the dielectric material layer facing the feature meets the surface of the substrate facing the feature and comprises at least one side wall and a bottom surface of the feature, a barrier layer coating the at least one side wall of the feature and extending to and coating the bottom surface of the feature, a continuous metal seed layer coating the barrier layer over the at least one side wall extending to and over the bottom surface of the feature, at least a remnant of a pre-electroplating layer coating at least an upper portion of the continuous metal seed layer over the at least one side wall of the feature, but not over the bottom surface of the feature and a substantially void free homogeneous metal feature fill material extending from the continuous metal seed layer coating the barrier layer over the bottom surface of the feature and on the pre-electroplating layer coating the continuous metal seed layer over the at least an upper portion of the at least one side wall of the feature to substantially fill the void in the layer of dielectric material, wherein the at least a remnant of the pre-electroplating layer coating the continuous metal seed layer over the at least an upper portion of the at least one side wall of the feature is comprised of a metal selected from a group of continuous metal seed layer bondable materials having an electrical resistance greater than the continuous metal seed layer coating the barrier layer over the at least one side wall extending to and over the bottom surface of the feature, and where present the at least a remnant of a pre-electroplating layer is disposed between the substantially void free homogeneous metal feature fill material and the metal seed layer coating the barrier layer over the at least one side wall of the feature.

Further implementations include a substrate structure comprising: a depression forming a feature in and below a surface of a dielectric layer on the substrate, a copper seed layer covering a barrier layer covering one or more side walls and a bottom surface of the feature, a remnant of a cobalt layer covering at least an upper portion of the copper seed layer on the one or more side walls of the feature and not covering the bottom surface of the feature, electroplating copper feature fill material to fill the feature from the bottom surface and cover the pre-electroplating layer covering the seed layer on the one or more side walls at least to the surface of the dielectric layer. The seed layer can be copper, ruthenium, palladium, or a copper, ruthenium, or palladium containing alloy. The pre-electroplating layer can have an electrical conductivity less than the seed layer and can be cobalt or a cobalt alloy.

Further implementations include a process of making a reliable electrical connection through a dielectric layer on a substrate comprising: depositing a seed layer covering at least one or more side walls and a bottom surface of a feature in and below a surface of the dielectric layer on the substrate, depositing a pre-electroplating layer covering at least an upper portion of the seed layer on the one or more side walls of the feature and not on a bottom surface of a feature in and below a surface of the dielectric layer on the substrate, and electroplating copper feature fill material to fill the feature from the bottom surface and cover the pre-electroplating layer covering the seed layer on the one or more side walls at least to the surface of the dielectric layer, wherein the pre-electroplating layer can have a conductivity less than the seed layer and can be cobalt or a cobalt alloy.

Utilizing a PVD process and chamber for deposition of the pre-electroplating layer can provide the further process efficiency of not having to move the substrate on which the pre-electroplating layer has been deposited by PVD to another processing chamber, as the PVD chamber can be configured to immediately perform the following process step where: depositing a pre-electroplating layer is performed in a PVD chamber and the subsequent step of etching of the dielectric layer and substrate to remove at least the pre-electroplating layer covering the seed layer on the bottom surface of the feature substantially without removing the pre-electroplating layer on the one or more side walls of the feature is also performed in that same PVD chamber.

### BRIEF DESCRIPTION OF THE DRAWINGS

So that the manner in which the above-recited features of the present disclosure can be understood in detail, a more particular description of the disclosure, briefly summarized above, may be had by reference to implementations, some of which are illustrated in the appended drawings. It is to be noted, however, that the appended drawings illustrate only typical implementations of this disclosure and are therefore not to be considered limiting of its scope, for the disclosure may admit to other equally effective implementations.

FIG. 1 (Prior Art) is a cross-sectional view of a portion of a prior art semiconductor device with a feature, in which a barrier layer and a seed layer have been deposited on the surfaces thereof;

FIG. 2 (Prior Art) is a cross-sectional view of the device of FIG. 1, schematically showing the differential growth of material deposited on side walls and the bottom surface of the feature during the process of copper electroplating as observed in the prior art;

FIG. 3 (Prior Art) is a cross-sectional view of the device of FIG. 1, in which the feature has been closed off leaving a void in the feature after conclusion of the prior art copper electroplating process;

FIG. 4 is a cross-sectional view of a semiconductor device having a barrier layer and a seed layer deposited in a feature and a cobalt layer deposited over the previously applied seed layer according to implementations described herein;

FIG. 5 is a cross-sectional view of the structure of FIG. 4 showing the cobalt layer of FIG. 4 having been removed from the top surface of the substrate and the bottom surface of the feature leaving a cobalt layer on the side wall of the feature according to implementations described herein;

FIG. 6 is a cross-sectional view of a portion of the semiconductor device of FIG. 5 after electroplating according to implementations described herein;

FIG. 7 is a flow chart illustrating one implementation of a process for forming a semiconductor device according to implementations described herein;

FIG. 8 is a cross-sectional view of a semiconductor device having a barrier layer and a seed layer deposited in a feature during modification of the seed layer according to implementations described herein;

FIG. 9 is a cross-sectional view of a semiconductor device is a cross-sectional view of a semiconductor device having a barrier layer and a modified seed layer deposited in a feature according to implementations described herein; and

FIG. 10 is a cross-sectional view of a portion of a semiconductor device after electroplating according to implementations described herein.

To facilitate understanding, identical reference numerals have been used, where possible, to designate identical elements that are common to the figures. It is contemplated that elements disclosed in one implementation may be beneficially utilized in other implementations without specific recitation.

### DETAILED DESCRIPTION

Electroplating is one process technology used to deposit Cu interconnect metal structures. A pattern in the shape of the desired structure is etched into the underlying inter-layer dielectric (ILD) material. Copper is then processed to fill the etched structures.

Copper atoms can readily diffuse into adjacent ILD (inter-layer dielectric) or other dielectric layers, which can compromise their integrity as insulators. Therefore a diffusion barrier layer is typically formed between the dielectric layer (ILD) and the copper layer/fill.

After patterning, a very thin barrier layer is deposited on top of the etched structure. Materials for the barrier layer include Tantalum (Ta), Tungsten Nitride (WN), Titanium Nitride (TiN), TiNₓSi_{y}, Tantalum Nitride (TaNₓ), Silicon Nitride (SiN), Tungsten (W), CoWP, NiMoP, NiMoB, Ruthenium (Ru), RuO₂, Molybdenum (Mo), and MoₓN_{y}, where x and y are non-zero numbers. The barrier layer may be deposited using a conventional chemical vapor deposition (CVD) process, physical vapor deposition (PVD) process, or other known deposition process.

After depositing the barrier layer, a seed layer is deposited which supports better adhesion of the Cu on the underlying material and acts as an electrode and a catalytic material during the plating process. Typical materials for the seed layer are compounds which include Cu, Pd, or other compounds of polymers and organic materials. Adhesion is defined by when the deposited layer will readily deposit on (bond to) the underlying layer, as at least partially in a mechanical engagement with the surface irregularities to create initially a mechanical bond then a chemical or electrochemical neutral or attractive condition with the adjacent material, in contrast to a repulsion. An example of a repulsion or a non adherent bond provides side by side materials which are individually (or separately) cohesive, their lowest energy state has a preference to and establishes bonds between atoms and molecules of itself rather than to other materials atoms and molecules. While an initial mechanical bond can be created between non adherent materials, differential stress cycling between the materials, such as might occur in repeated heating and cooling cycles due to a differential in the coefficient of thermal expansion will cause non-adhered bonds to separate, while the bond between “adhered” materials will remain continue to operate acceptably and within design specifications.

Feature fill techniques use electroplating to fill very small features (e.g., ˜10 nm in width) with copper. To facilitate such filling a “seed layer” must provide enough electrical conductance across the wafer, so that a uniform thickness of copper can be deposited during electroplating. To electroplate copper, the underlying surface must carry a current to create a charge across its surface to attract ions from the electroplating solution during the electrochemical electroplating process. Deposition of the copper seed layer is typically performed by any suitable process, such as PVD.

The seed layer must be conductive enough across the face of the wafer that a uniform electroplating process can be carried out. A seed layer that is too thin does not achieve bulk conductivity. Further, thin copper seed layers generally do not coat the barrier layer in a uniform manner, resulting in the inability to properly apply a subsequent electro-chemically deposited copper layer. When a discontinuity is present in the seed layer, the portion of the seed layer that is not electrically connected to the bias power supply does not receive deposition during the electroplating process. This is particularly prevalent with high aspect ratio, sub-micron features, where the bottom surface and lower side walls of these features are especially difficult to coat using PVD. Thus, in general, thicker seed layers are desirable to achieve uniform electroplating.

Minimum thicknesses for copper seed layers have been as much as 30 nm, however with reduced feature sizes copper seed layer thicknesses have been reduced to a range of 100 Å to 300 Å, e.g., 100, 200 or 300 Å.

However, a second requirement limits the thickness of the combined barrier and seed layer on the side walls of the feature or vias to be filled, and also is a factor in determining the maximum aspect ratio of a feature that can be successfully filled by electroplating. Presently, PVD has been used to deposit the seed layers. PVD forms a seed layer having a much thicker layer on the planar surface (“field”) of the wafer than within the small features such as vias and trenches, i.e., the deposition is non-conformal. The thicker material in the field allows current to be conducted across the wafer, while there is sufficient copper in the features to allow electroplating in the features. With lower aspect ratio features, e.g., <3:1, the opening of feature stays open long enough to allow a void-free fill with electroplating.

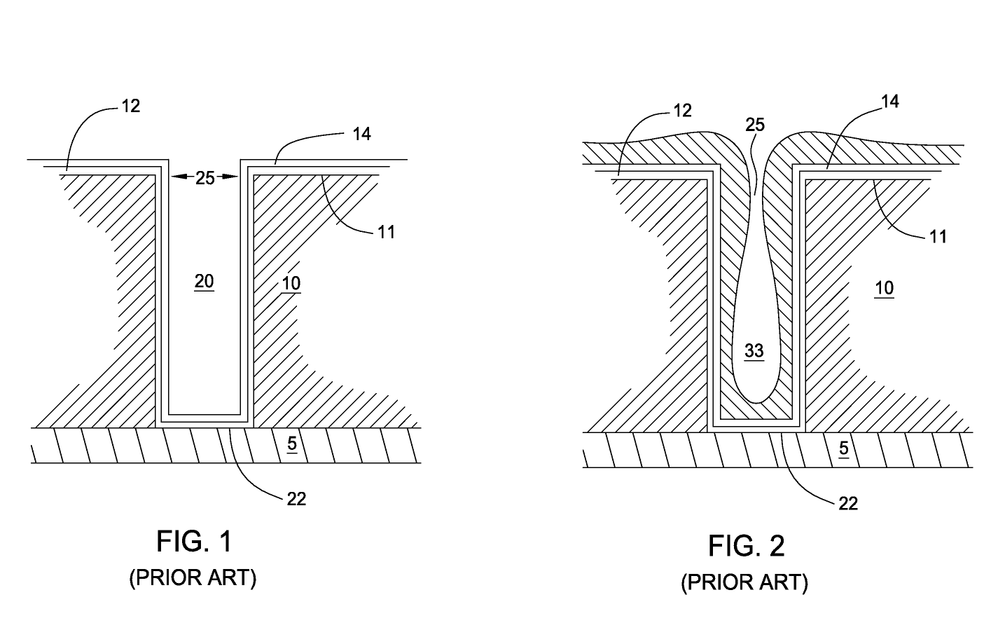

Successive reduction in feature sizes has been achieved by increasing difficulty in this process. When the seed layer is formed on the side walls as well as the bottom surface of the feature, the electroplating process deposits the metal on both surfaces within the feature. With high aspect ratio features, as can be seen in FIGS. 1, 2, and 3 which show the progression of Cu deposition growth during electroplating, the opening 25 (in new generation devices—where the nominal feature gap opening dimensions are in the range of 32 nm and less—(gap in the surface of the dielectric material layer created by the aperture (or depression) therein is can be 32 nm or less)) of the feature can become “closed off” 27 before the bottom up fill process (ample to fill prior art features having a gap opening dimension of 60 nm or greater) reaches the full height of the thickness of the dielectric layer to fully fill the feature with substantially void-free fill material, in most instances copper.

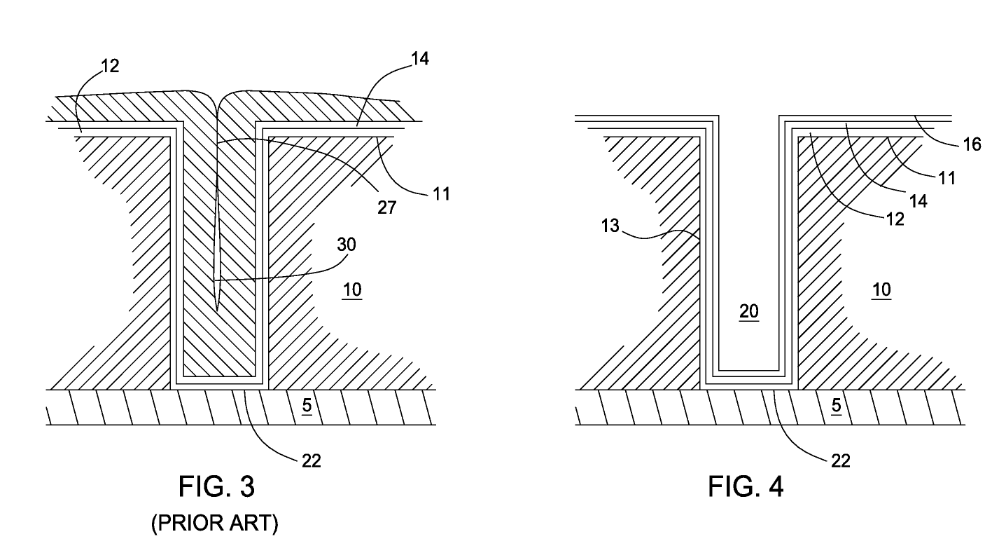

The electroplated metal growth on the side walls tends to close off the feature at the aperture opening 25 before the lower portion, e.g., 33, of the feature has completely grown from the feature bottom surface (also known as the top surface of the substrate facing the aperture or depression in the dielectric material layer), resulting in a void 30 forming within the feature, as shown in FIG. 3. The presence of the void 30 changes the material and operating characteristics of the interconnect feature and may eventually cause improper operation and premature breakdown of the device. The conductive element, line, to be efficient, must carry near its practical maximum current density as established and known by persons skilled in the art in current state of the art devices. The goal is to achieve the same current flow density or higher in smaller features in future devices. Current feature sizes sub-micron, high aspect ratio semiconductor substrate features providing reliable bottom up accumulation of the electroplating fill material in sizes associated with current technology node of 45 nm but will not work in projected future technology nodes of 22, 15, 11, and 8 nm.

Implementations described include an apparatus and process which allow electroplating to fill sub-micron, high aspect ratio features (e.g., 20) utilizing a pre-electroplating (non-copper) layer 16 over the feature side wall 13 between the seed layer 14 and the electroplated copper fill material 40. The pre-electroplating (e.g., Cobalt) layer 16 after processing and in the final structure remains mainly over the feature side walls 13, i.e., the vertical surfaces of the feature, with little or no pre-electroplating material on the bottom surfaces 22 of the features to be filled. The presence of this pre-electroplating layer over the side wall finds a more reliable bottom up electroplating deposition within the feature, to achieve a reliable void-free feature fill capability.

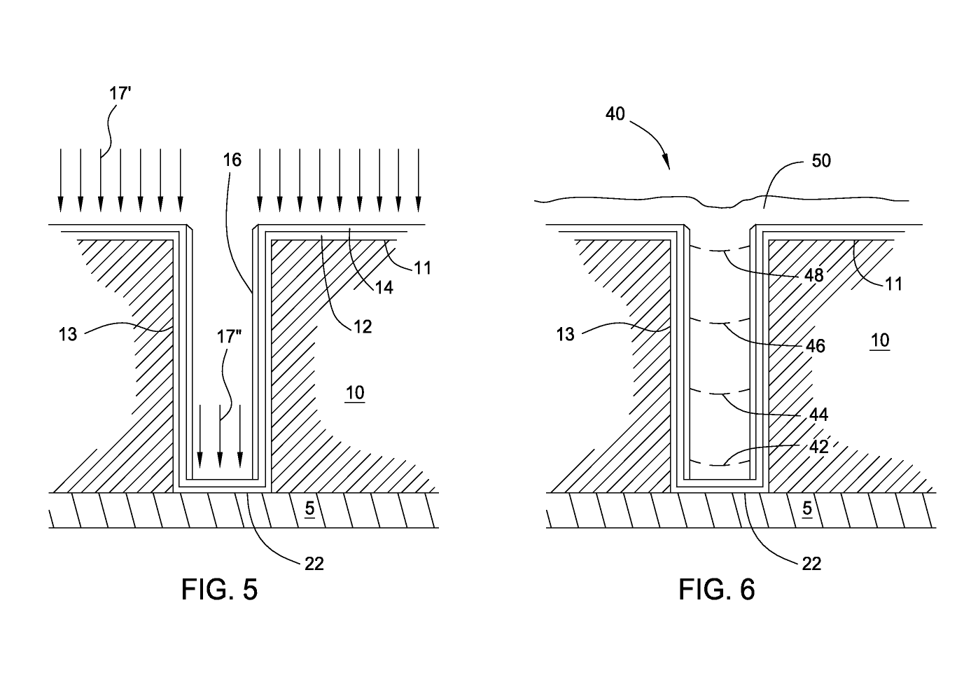

In one implementation (as in the prior art FIGS. 1-3), a conformal barrier layer 12 is first deposited over the dielectric layer 10 and features, where the conformal barrier layer 12 forms on all planar surfaces 11 and side wall surfaces 13 of the dielectric layer 10 and the feature 20 contained therein. A seed layer 14 (such as copper) is then deposited, such as by PVD, on the conformal barrier layer 12, where the seed layer 14 forms on the conformal barrier layer 12 and over all planar surfaces 11 and side wall surfaces 13 of the dielectric layer 10 and the feature 20 contained therein. Next, a non-copper/pre-electroplating layer 16 (FIG. 4) is deposited on the seed layer 14, the exposed surfaces of the non-copper/pre-electroplating layer 16 are directionally etched (FIG. 5) to remove the non-copper pre-electro plating layer 16 from the planar upward facing surfaces 11 of the dielectric layer 10 and to remove the non-copper pre-electroplating layer 16 from the bottom surface 22 of the feature 20, leaving the non-copper pre-electroplating layer 16 only over the side walls 13 of the feature 20. The arrows 17′ represent the direction of the electric field influencing the ions in the etching gas to collide with the top (planar) surface of the pre-electroplating layer to remove it during the directional etch process. The arrows 17″ similarly show the direction of the electric field at the bottom surface 22 of the feature 20 in the dielectric layer. The vertical side wall 13 is substantially unaffected by the etch process and so the pre-electroplating layer 16 deposited over the side wall 13 remains intact after the etch process is completed. Electro-plating is then performed to fill the feature 20.

FIGS. 4-6 show cross-sectional views of a portion of a semiconductor wafer during various stages of an electroplating feature filling process as described herein.

First, a dielectric or insulating layer 10, such as a silicon oxide, is conventionally formed over a semiconductor wafer. The dielectric layer 10 can be deposited over a silicon substrate 5, in which transistor elements or other active component areas have been formed, over patterned metal layers, or over any other suitable layers that require electrical connection to areas on the same or adjacent layers. Dielectric layer 10 is then etched to form features 20, such as vias, over selected areas for electrical connection. Features with aspect ratios up to about 10:1 are fillable. Note that other features can also be etched from the dielectric, such as contacts, lines, damascene and dual damascene structures having a via and a trench portion. Etching can be performed with conventional methods, such as photolithography techniques in which deposited photoresist is patterned and used as a mask to etch dielectric layer.

As shown in FIG. 4, a conformal barrier layer 12 has been deposited on the dielectric layer 10. Barrier layer 12 forms a relatively uniform layer of material on the planar surface 11 of the dielectric, the side walls of feature 20, and the bottom surface 22 of feature 20. The barrier layer can be Tantalum (Ta), Tungsten Nitride (WN), Titanium Nitride (TiN), TiNₓSi_{y}, Tantalum Nitride (TaNₓ), Silicon Nitride (SiN), Tungsten (W), CoWP, NiMoP, NiMoB, Ruthenium (Ru), RuO₂, Molybdenum (Mo), and MoₓN_{y}, where x and y are non-zero numbers. This list is not exhaustive, and other materials that could be used are ones that can be deposited with good adhesion and that when deposited as a layer approximately 2-10 nm thick show acceptable barrier layer performance. These films can be deposited by PVD, CVD, or ALD techniques (PVD is typically used). The deposited film is typically 4 nm thick. Barrier layer 12 prevents atoms from the subsequently deposited metal layers (e.g., Cu) from migrating (out) into the dielectric layers, since this can cause the integrity of the dielectric layer to be compromised (damages the device) or cause voids in the conductors because of out-diffusion of the copper.

As shown in FIG. 4, a seed layer 14, such as a copper layer, has also been deposited over the dielectric and feature area. Deposition could be performed by using a physical vapor deposition (PVD) tool using (sputter source technology).

Next, in FIG. 4, a pre-electroplating layer 16 (e.g., cobalt, or a copper alloy or another material that slows the electroplating process to be less (ideally substantially less) than the rate of the electroplating rate of accumulation from the bottom surface 22, e.g., the side wall has a 10% (or 15% or 20% or 25%) electroplating rate of the rate of material accumulation accumulating from the bottom surface 22, (elements and alloys of Rh, Pd, Ni, Zn, Cd, Cr, W, Mo, Ru alone or in combination are possible materials that could work as described herein for the side wall electroplating accumulation rate retarding layer) is deposited using a CVD process, or a PVD process over the seed layer 14 already in place. The electroplating rate on the side wall(s) should be so low that they do not pinch off the bottom up fill accumulation (growth, deposition) and create voids in the metal (copper) material being deposited during the electroplating process. Whether there is one tubular shaped side wall (providing a tubular via feature with facing side surfaces) or separate side walls on opposite side of a line feature, the feature still have facing (essentially opposing) walls. The rate of deposition of metal (copper) material on those opposing walls will essentially cause the rate of closure of the feature gap to be double the rate of deposition on one sidewall. For example, in a feature having a 5 to 1 aspect ratio, depth to width (assuming 5 dimension units of depth and 1 dimension unit of width), initially assuming no side wall deposition, a bottom up fill could take 5 deposition time increment units to fill the feature from bottom to top. If the side wall growth were 100% of the bottom up deposition rate, the “one” unit wide feature would be choked off in 0.5 deposition time increment units while only 0.5 dimension units of metal thickness would have been deposited at the bottom of the feature.

To allow time for the bottom up deposition in the feature to take place leaving an opening of 50% of the top gap opening available would require that the side wall deposition rate be 5% of the bottom up deposition rate (assuming a constant side wall deposition rate). However, in practice, once a continuous metal (copper) layer has initially been formed on a side wall face and is electrically connected to the metal copper seed layer, then the continuous metal layer on the side wall will be charged to a similar electrical charge as the metal seed layer during electroplating. Once the side wall is electrically charged, like the seed layer, metal (copper) deposition will take place on the initially deposited material on the side wall face without a reduction or obstruction in rate. With this in mind, a successful bottom up fill requires that the initial rate of deposition of electroplating material on the sidewall be close to zero. A slow accumulation of atoms (or molecules) will take place on the side wall surface until a current carrying stable electrical connection is achieved with the metal seed layer, at that point deposition will occur as fast as the bottom up feature fill deposition rate and choke off the top of the feature from bottom up deposition (growth) if it is not already near full. In one implementation, pre-electroplating layer has a thickness between 1 angstrom and 20 angstroms, with a typical thickness of 10 angstroms. Because there may be little or no conductive layer material on the side walls of the feature, the pre-electroplating layer must have good adhesion to as well as acting as a conductor with a lower conductivity or higher resistance than the underlying copper seed layer. Further, the materials for pre-electroplating layer must be capable of bonding to the fill material when the fill material is electroplated in a bottom-up accumulation in the feature (good bonding is sometimes referred to as good adhesion).

FIG. 5 shows an etch process where positive ions of an etching gas (e.g., argon) that are attracted towards the semiconductor wafer by the electric field within a plasma formed over the dielectric layer. As a result the ions move in a direction normal to the surface of the dielectric layer and etch the top planar and feature bottom surfaces to remove the pre-electroplating layer 16 from those surfaces leaving the pre-electroplating layer 16 only on the feature side wall 13. The pre-electroplating layer 16 remaining on the side wall acts to control (reduce) the rate of copper deposition on the side wall during electroplating (as compared to a side wall surface which has no pre-electroplating layer 16—normally copper on copper electroplating takes place. The materials and thickness of the pre-electroplating layer 16 can be adjusted and investigated to empirically determine the most efficient idealized case where a minimal thickness of the layer 16 is deposited while the bottom up electroplating still satisfactorily occurs in small size device features. Satisfactory performance is defined by having a current density through the feature exceeding the current density during normal operation in features having an opening size of approximately 50 nm (the current state-of-the-art). Satisfactory performance is defined as void free or substantially void free electroplating fill material as determined by persons skilled in the art.

When PVD (or another process suitable for directionally (geometrically) influenced material deposition) is used to deposit the pre-electroplating layer on the seed layer the non-conformability may be tuned to reduce or avoid deposition of the pre-electroplating on or near the bottom surface (e.g., 22) of the feature 20, then the etching step can be eliminated. The lower portion of the sidewall (or near the bottom surface) can be defined as being a distance up from the bottom surface about equal to the width dimension of the feature.

In the instance when the pre-electroplating deposition is performed using a PVD process, an efficiency associated with this process is the ability to immediately transition the PVD deposition process in a chamber in which plasma is generated for the PVD process to an argon etch process for directionally removing the pre-electroplating process without having to move the substrate being processed to another processing chamber.

A conventional electroplating process, in which features are filled from the bottom up as shown by intermediate fill level indicator dashed lines 42, 44, 46, 48, to top out at a feature filled level 50. The process of electroplating may cause the pre-electroplating layer to thin and disappear completely in portions of the feature side wall where it was originally present after etching. It is expected that at least some remnants of the pre-electroplating layer will be able to be detected in a structural investigation of the fill material in a feature of a dielectric layer at or near an original position of the pre-electroplating layer in the feature after the electroplating process has concluded. During electroplating the feature is typically filled with copper or other suitable material without any voids, is shown in FIG. 6. Planarization, such as by CMP, removes the excess copper, i.e., the portion of the feature filled level 50 of copper above the top surface of the dielectric layer 10, and further processing continues.

Although Co is the preferred pre-electroplating layer material, other materials such as Pt, Pd, and Ru may be used. They have the advantage of not being attacked by conventional plating chemistries, and therefore may be deposited as a thin layer.

This approach is counter intuitive and reduces the electroplating rate on the side wall while still maintaining a high (acceptable) current flow through the bottom surface of the feature to promote the electroplating rate at the bottom surface of the feature.

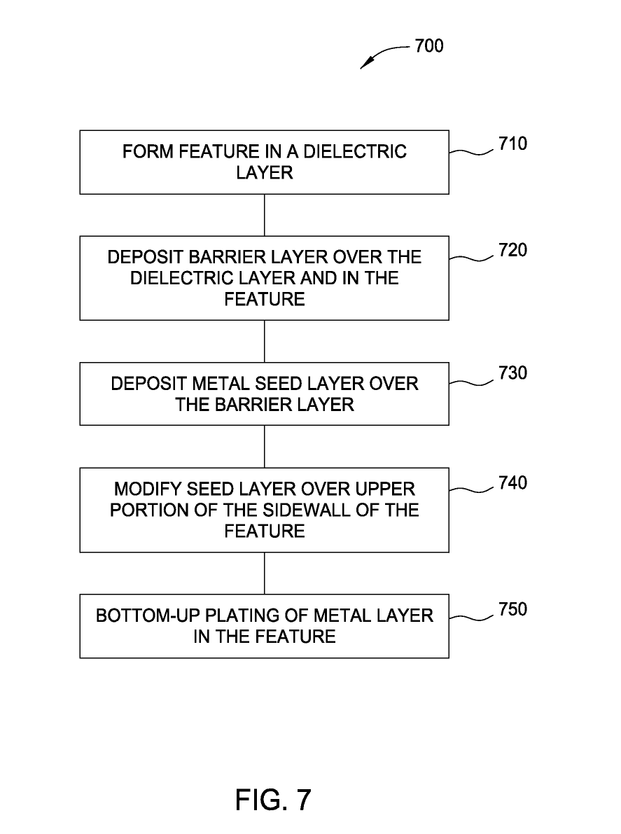

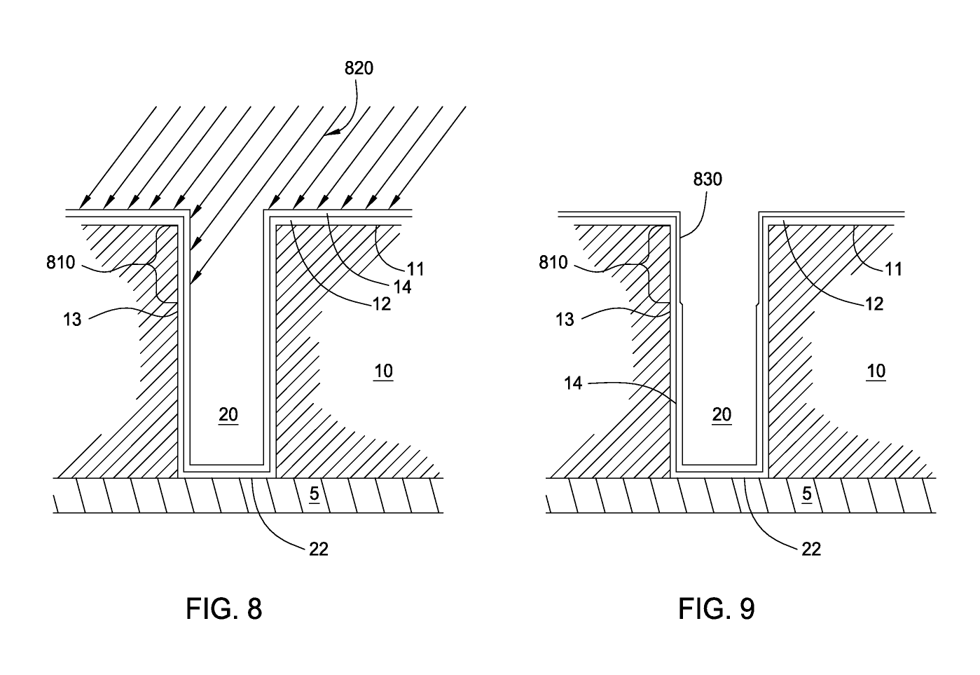

FIG. 7 is a flow chart illustrating one implementation of a processing sequence 700 for forming a semiconductor device according to implementations described herein. FIGS. 8-10 illustrate a schematic cross-sectional view of a feature 20 as the various processing steps of processing sequence 700 (FIG. 7) are performed.

At block 710, a feature 20 is formed in the dielectric layer 10 formed over the substrate 5. FIG. 8 illustrates a cross-sectional view of the feature 20 formed into the planar surface 11 of the dielectric layer 10. As previously described, the feature 20 has at least one sidewall surface 13 and a bottom surface 22. The feature 20 may be an aperture such as contact holes, vias, or trenches. In some implementations where the feature is a via, the via may have a high aspect ratio (e.g., AR ˜5-50). A nominal minimal dimension across a gap in the surface of the dielectric material layer created by the feature therein may be 32 nm or less. A nominal minimal dimension across a gap in the surface of the dielectric material layer created by the feature therein may be 15 nm or less. A nominal minimal dimension across a gap in the surface of the dielectric material layer created by the feature therein may be 11 nm or less. The substrate 5 may comprise a semiconductor material such as, for example, silicon, germanium, or silicon germanium. The feature 20 may be formed in the dielectric layer 10 using conventional lithography and etching techniques.

At block 720, a barrier layer 12 is formed over the dielectric layer 10 and in the feature 20 as depicted in FIG. 8. The barrier layer 12 may be formed over the planar surfaces 11 of the dielectric layer 10 and over the at least one sidewall 13 and bottom surface 22 of the feature 20. The barrier layer 12 may be a conformal barrier layer. The barrier layer 12 may be a single deposited layer, or multiple deposited layers, containing ruthenium (Ru), titanium (Ti), titanium nitride (TiN), tungsten (W), tungsten nitride (WN), Tantalum (Ta), tantalum nitride (TaN) or other alloy containing these materials. The barrier layer may be Tantalum (Ta), Tungsten Nitride (WN), Titanium Nitride (TiN), TiNxSiy, Tantalum Nitride (TaNx), Silicon Nitride (SiN), Tungsten (W), CoWP, NiMoP, NiMoB, Ruthenium (Ru), RuO₂, Molybdenum (Mo), and MoₓN_{y}, where x and y are non-zero numbers. This list is not exhaustive, and other materials that could be used are ones that can be deposited with good adhesion and that when deposited as a layer approximately 0.1-10 nm thick show acceptable barrier layer performance. The barrier layer can be deposited by PVD, CVD, or ALD techniques (PVD is typically used). The deposited film is typically 4 nm thick. Barrier layer 12 prevents atoms from the subsequently deposited metal layers (e.g., Cu) from migrating (out) into the dielectric layer 10, since this can cause the integrity of the dielectric layer to be compromised (damages the device) or cause voids in the conductors because of out-diffusion of the copper. In some implementations, the barrier layer 12 may have a thickness from about 0.5-5 nm thick.

At block 730, a metal seed layer 14 is formed over the barrier layer 12. The metal seed layer 14 may be deposited using a physical vapor deposition (PVD), chemical vapor deposition (CVD), electroless deposition or atomic layer deposition (ALD) processes. The metal seed layer 14 may be a conformal metal seed layer. In some implementations, the metal seed layer 14 deposition process may be conducted in the same deposition chamber as the barrier layer deposition process, described above. In some implementations, the metal seed layer 14 may be a copper (Cu) layer, a ruthenium (Ru) layer, a palladium (Pd) layer, a nickel (Ni) layer, a cobalt (Co) layer, or a layer that is an alloy containing one or more of these elements. In some implementations, the deposited metal seed layer 14 is from about 0.5 nm to about 250 nm thick. In some implementations, the deposited metal seed layer 14 is from about 100 nm to about 200 nm thick. In some implementations, the deposited metal seed layer 14 is from about 2 to about 20 nm.

At block 740 a portion of the seed layer 14 on an upper portion 810 of the sidewall 13 of the feature 20 is modified. In some implementations, the upper portion 810 of the sidewall 13 is from the planar surface 11 to may include up to the upper half (e.g. 50%) of the total length of the seed layer 14 along the sidewall 13. The upper portion 810 of the sidewall 13 may include up to the upper third (e.g. 33%) of the total length of the seed layer 14 along the sidewall 13. Modification of the seed layer 14 may include complete removal of at least a portion of the seed layer 14 or a redistribution of the material of the seed layer 14. In some implementations, modification of the seed layer involves reducing the thickness of the seed layer 14. In some implementations, the thickness of the seed layer 14 may be reduced by from about 1 Å to about 50 Å relative to the remainder of the metal seed layer. In some implementations, the thickness of the seed layer 14 may be reduced by from about 5 Å to about 10 Å relative to the remainder of the metal seed layer.

The seed layer 14 may be modified using an etching process, for example, a reactive ion etching process or a sputtering etching process. In some implementations, modification of the seed layer 14 may be performed using a directional etching process as depicted in FIG. 8. In some implementations, the directional etching process may be a directional etching process. The etching process may be performed using gases selected from the group of: argon (Ar), nitrogen (N₂), hydrogen (H₂), neon (Ne), helium (He), oxygen (O₂) and combinations thereof. In some implementations, a portion of the seed layer 14 along the upper portion 810 of the sidewall 13 may be directionally etched to modify the seed layer 14. The seed layer 14 on the planar surface 11 may be thinned or completely removed during the modification process. The arrows 820 represent the direction of gas ion movement, due to the generation of an electric field near the planar surface 11 of the dielectric layer 10 during processing, which causes the ions to collide with the seed layer 14 during the directional etch process. The seed layer 14 along the upper portion 810 of the side wall 108 may be thinned. Although the remaining modified portion 830 of the seed layer 14 may provide a conductive path, the resistance of the modified portion 830 of the seed layer 14 is typically very high and as a result, a significant amount of plating does not take place along the upper portion 810 of the sidewall 14 where the modified portion 830 of the seed layer 14 is present, thus providing for bottom-up fill.

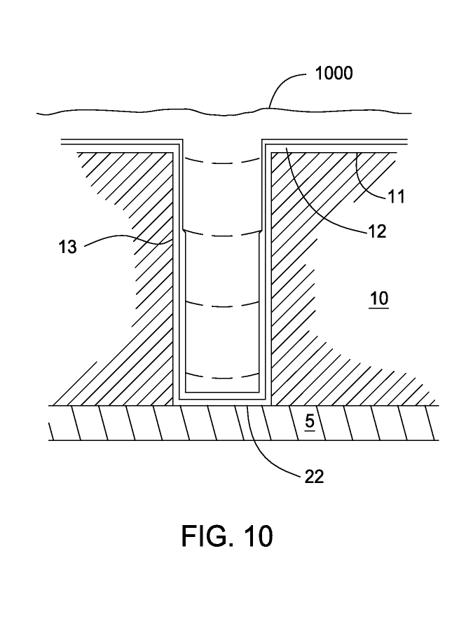

At block 750, bottom-up filling of the feature 20 with a metal layer 1000 is performed by a plating process as depicted in FIG. 10. The plating process may be an electroplating process or an electroless plating process. In some implementations, the feature 102 is preferentially filled by the metal layer 1000 from the bottom surface 22 of the feature 20 until the layer is about level with the planar surface 11 (e.g., bottom-up fill). In some implementations, the metal layer 1000 may be a copper (Cu) layer, a cobalt (Co) layer, a nickel (Ni) layer, a silver (Ag) layer or a layer that is an alloy containing one or more of these elements. In some implementations, the feature 20 is filed using a multilayer fill process in which two or more layers are sequentially deposited to fill the feature 20. In general, the metal layer 1000 may be deposited using an electroplating deposition solution that contains one or more metal ion sources that allows the deposition of a layer that contains one or more metals. In one implementations, one of the metals ions is a copper ion and the other metal ion(s) are a metal selected from a group consisting of aluminum (Al), indium (In), molybdenum (Mo), tungsten (W), manganese (Mn), cobalt (Co), tin (Sn), nickel (Ni), magnesium (Mg), rhenium (Rh), beryllium (Be), phosphorus (P), boron (B), gallium (Ga), or ruthenium (Ru). In some implementations, a current of from about 0.5 Amps to 2 Amps is used. In some implementations, the deposition bias generally has a current density of from about 5 mA/cm² and about 20 mA/cm².

In some implementations of the processing sequence 700, any remaining seed layer 14 and/or barrier layer 12 may be removed from the planar surface 11 by use of a material removal process, such as an electrochemical process or chemical mechanical polishing process (CMP). In some implementations, the seed layer and/or barrier layer 12 may be removed from the planar surface 11 during the process of block 740. In some implementations, this process includes removing any over-plating leftover after performing the deposition of the metal layer 1000. The device may also be exposed to a cleaning process to remove any plating solution and or wet contact solution. The cleaning process may comprise at least one of a spin, a rinse, and a dry.

While the foregoing is directed to implementations according to the present disclosure, other and further implementations may be devised without departing from the basic scope thereof, and the scope thereof is determined by the claims that follow.

1. A process of making a reliable electrical connection through a dielectric layer on a substrate comprising:
depositing a barrier layer over at least one or more side walls and a bottom surface of a feature in and below a surface of a dielectric layer on the substrate;
depositing a metal seed layer over the barrier layer covering the at least one or more side walls and the bottom surface of the feature; and
modifying an upper portion of the metal seed layer to promote bottom-up plating of a metal layer in the feature.

2. The process of claim 1, further comprising:
electroplating copper feature fill material to fill the feature from the bottom surface and cover the metal seed layer on the one or more side walls at least to the surface of the dielectric layer.

3. The process of claim 1, wherein the modifying an upper portion of the metal seed layer comprises etching the upper portion of the metal seed layer.

4. The process of claim 3, wherein the upper portion of the metal seed layer is etched using a reactive ion etching process or a sputtering etching process.

5. The process of claim 4, wherein the upper portion of the metal seed layer is etched using a directional etching process.

6. The process of claim 1, wherein a nominal minimal dimension across a gap in the surface of the dielectric material layer created by the feature therein is 32 nm or less.

7. The process of claim 1, wherein a nominal minimal dimension across a gap in the surface of the dielectric material layer created by the feature therein is 15 nm or less.

8. The process of claim 1, wherein a nominal minimal dimension across a gap in the surface of the dielectric material layer created by the feature therein is 11 nm or less.

9. The process of claim 1, wherein the metal seed layer is one compound selected from a group of compounds which include copper (Cu) or palladium (Pd) or is copper or an alloy thereof.

10. The process of claim 1, wherein the metal seed layer is a copper seed layer.

11. The process of claim 1, wherein the upper portion of the sidewall includes from the planar surface to about 50% of the total length of the metal seed layer along the sidewall.

12. The process of claim 1, wherein the upper portion of the sidewall includes from the planar surface to about 33% of the total length of the seed layer along the sidewall.

13. The process of claim 1, wherein the metal seed layer has an initial thickness from about 2 nm to about 20 nm.

14. The process of claim 1, wherein modifying an upper portion of the metal seed layer includes reducing a thickness of the metal seed layer from about 5 Å to about 10 Å relative to the remainder of the metal seed layer.

15. A substrate structure comprising:
a feature having a depression in and below a surface of a dielectric layer on a substrate;
a barrier layer covering one or more side walls and a bottom surface of the feature; and
a metal seed layer covering the barrier layer covering one or more side walls and a bottom surface of the feature, wherein an upper portion of the metal seed layer is modified to promote bottom-up plating of a metal layer in the feature.

16. The substrate structure of claim 15, further comprising a metal layer filling the depression from the bottom surface and covering the metal seed layer on the one or more side walls to the surface of the dielectric layer.

17. The substrate structure of claim 16, wherein a nominal minimal dimension across a gap in the surface of the dielectric material layer created by the feature therein is 32 nm or less.

18. The substrate structure of claim 17, wherein the continuous metal seed layer is one compound selected from a group of compounds which include copper (Cu) or palladium (Pd) or is copper or an alloy thereof.

19. The substrate structure of claim 17, wherein the upper portion of the sidewall includes from the planar surface to about 50% of the total length of the metal seed layer along the sidewall.

20. The substrate structure of claim 15, wherein the modified upper portion of the metal seed layer has a thickness reduced from about 5 Å to about 10 Å relative to the remainder of the metal seed layer.
